(19) United States
(12) Patent Application Publication
(10) Pub. No.: US 2022/0238392 A1
(43) Pub. Date: Jul. 28, 2022

(54) Method for detecting optimal production conditions of wafers

(71) Applicant: United Semiconductor (Xiamen) Co., Ltd., Xiamen (CN)

(72) Inventor: Long Wang, Shamen City (CN)

(21) Appl. No.: 17/189,214

(22) Filed: Mar. 1, 2021

(30) Foreign Application Priority Data
Jan. 26, 2021 (CN) 202110102203.1

(51) Int. Cl. H01L 21/66; H01L 21/027; H01L 21/265; H01L 21/266

(52) U.S. Cl. CPC H01L 22/14; H01L 21/266; H01L 21/26513; H01L 21/0274

(57) ABSTRACT

The invention relates to a method for detecting optimal production conditions of wafers, the method includes the following steps: a wafer is provided, a plurality of regions are defined on the wafer, the plurality of regions at least includes a first region and a second region, a first photolithography step is performed to expose the first region of the plurality of regions, a first ion implantation step is then performed, ions are doped in the first region, the first region has a first ion doping concentration. Next, a second photolithography step is performed to expose the second region, a second ion implantation step is performed and ions are doped in the second region, the second region has a second ion doping concentration. Afterwards, the electrical characteristics of the first region and the second region are respectively detected.

### BACKGROUND OF THE INVENTION

### 1. Field of the Invention

The invention relates to the field of semiconductors, in particular to a step for testing wafers, which can reduce wafer loss during wafer acceptance test (WAT).

### 2. Description of the Prior Art

In the semiconductor manufacturing process, a plurality of steps are performed on a wafer to form a plurality of different electronic components on the wafer. In order to ensure the quality of electronic components, test key are often formed on scribe line on the wafer, and then wafer acceptance test (WAT) is performed on the electronic components to test the electrical characteristics of the electronic components.

The purpose of wafer acceptance test is to make a preliminary electrical test on the wafer as the basis of wafer quality assurance. The tested electrical properties, such as capacitance, voltage, resistance, etc., can ensure the normal operation of electronic components. Therefore, by testing the electrical properties of the wafer, it can reflect whether the wafer is normal during production, and avoid the problem of low component quality.

### SUMMARY OF THE INVENTION

The invention relates to a method for detecting optimal production conditions of wafers, the method includes the following steps: a wafer is provided, a plurality of regions are defined on the wafer, the plurality of regions at least includes a first region and a second region, a first photolithography step is performed to expose the first region of the plurality of regions, a first ion implantation step is then performed, ions are doped in the first region, the first region has a first ion doping concentration. Next, a second photolithography step is performed to expose the second region, a second ion implantation step is performed and ions are doped in the second region, the second region has a second ion doping concentration. Afterwards, the electrical characteristics of the first region and the second region are respectively detected.

The invention relates to a method for detecting optimal production conditions of wafers, the method includes the following steps: firstly, a wafer is provided, a plurality of regions are defined, the plurality of regions at least includes a first region and a second region, a first photolithography step is performed to expose the first region of the plurality of regions with a first exposure energy, and to form a first pattern in the first region, the first pattern has a first exposure critical dimension. Next, the second region of the plurality of regions is exposed with a second exposure energy, and to form a second pattern in the second region, the second pattern has a second exposure critical dimension, and the electrical characteristics of the first region and the second region are detected respectively.

The invention is characterized in that, in the wafer testing step, in order to reduce the loss of the wafer, the wafer can be divided into different regions, and respective processes and electrical tests can be performed in different regions. Therefore, different regions can provide different test parameters and measurement results. In this way, multiple sets of experimental results can be measured on the same wafer, thus reducing wafer loss and cost.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 shows a schematic top view of a semiconductor wafer in the process of testing the semiconductor wafer according to the present invention.

FIG. 2A, FIG. 2B, FIG. 2C, and FIG. 2D are schematic diagrams showing the top view of a semiconductor wafer when the lithography step and the ion implantation step are performed in the process of testing the semiconductor wafer according to an embodiment of the present invention.

FIG. 3A and FIG. 3B show the top view of a semiconductor wafer for testing the influence of different exposure energies on the critical dimensions of different regions according to another embodiment of the present invention.

### DETAILED DESCRIPTION

To provide a better understanding of the present invention to users skilled in the technology of the present invention, preferred embodiments are detailed as follows. The preferred embodiments of the present invention are illustrated in the accompanying drawings with numbered elements to clarify the contents and the effects to be achieved.

Please note that the figures are only for illustration and the figures may not be to scale. The scale may be further modified according to different design considerations. When referring to the words “up” or “down” that describe the relationship between components in the text, it is well known in the art and should be clearly understood that these words refer to relative positions that can be inverted to obtain a similar structure, and these structures should therefore not be precluded from the scope of the claims in the present invention.

In some embodiments, when testing a semiconductor wafer, a specific experimental parameter is usually given to the whole wafer, and then wafer acceptance test (WAT) is performed on the semiconductor wafer. For example, taking the test of the influence of ion implantation concentration in semiconductor wafers on the subsequent semiconductor devices as an example, firstly, a plurality of semiconductor wafers can be provided, then one of the semiconductor wafers is doped with ions with a specific concentration (for example, the ion implantation concentration is N), and then the WAT is performed after the subsequent electronic devices are formed. Then, the other semiconductor wafers can be doped with ions with different ion concentrations (for example, the ion implantation concentrations on the other three semiconductor wafers are N+1, N+2 and N+3, respectively), and then the WAT is performed after the electronic components are formed respectively. In the above embodiment, a plurality of semiconductor wafers (for example, 4 wafers) need to be consumed in order to obtain a plurality of experimental test results. Therefore, it is not conducive to cost saving.

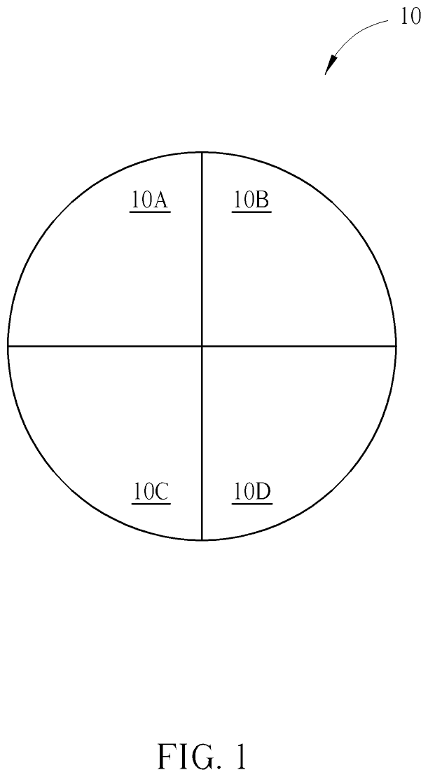

FIG. 1 shows a schematic top view of a semiconductor wafer in the process of testing the semiconductor wafer according to the present invention. As shown in FIG. 1, a semiconductor wafer 10 is divided into a plurality of regions, such as a first region 10A, a second region 10B, a third region 10C and a fourth region 10D. It should be noted that the division of the semiconductor wafer 10 into four regions in the present invention is only an exemplary illustration, and the present invention is not limited thereto. In other words, the present invention can also divide the semiconductor wafer 10 into more or less regions, which is also within the scope of the present invention.

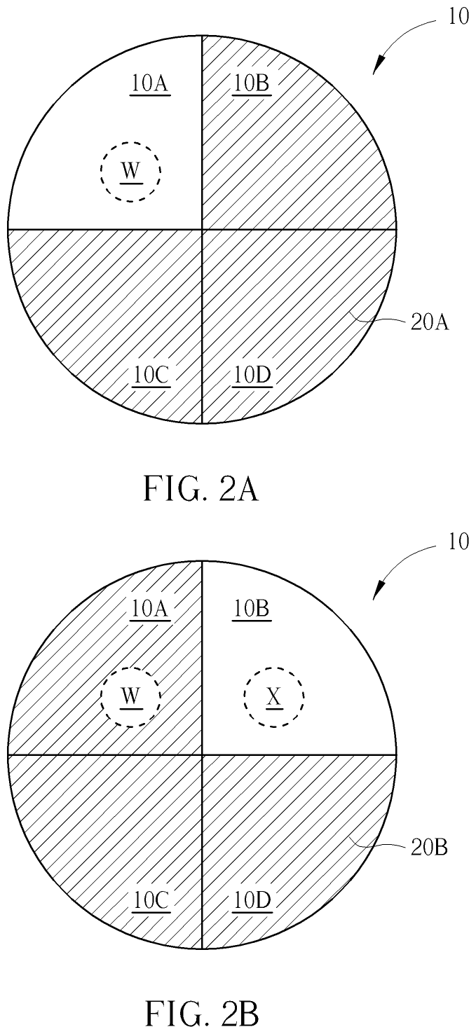

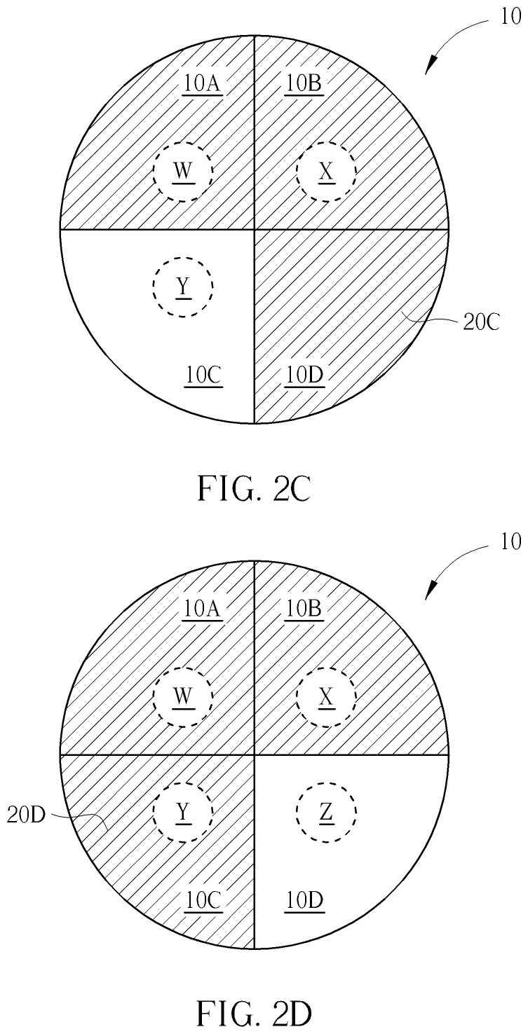

FIG. 2A, FIG. 2B, FIG. 2C, and FIG. 2D are schematic diagrams showing the top view of a semiconductor wafer when the lithography step and the ion implantation step are performed in the process of testing the semiconductor wafer according to an embodiment of the present invention. First, in FIG. 2A, a mask layer 20A (e.g., a photoresist layer) is formed on the semiconductor wafer 10 by a first photolithography step and a mask, and the mask layer 20A covers other regions except the first region 10A to expose the first region 10A. Then, a first ion implantation step is performed on the semiconductor wafer 10 to dope the first region 10A with ions with a concentration of W.

Next, as shown in FIG. 2B, after removing the mask layer 20A, a photoresist layer (not shown) is re-formed on the semiconductor wafer 10, and then a mask layer 20B (e.g., a photoresist layer) is formed on the semiconductor wafer 10 by a second photolithography step with the same mask used in the above-mentioned step of FIG. 2A, and the mask layer 20B covers other regions except the second region 10B to expose the second region 10B. Then, a second ion implantation step is performed on the semiconductor wafer 10 to dope the second region 10B with ions with a concentration of X.

Next, as shown in FIG. 2C, after removing the mask layer 20B, a photoresist layer (not shown) is re-formed on the semiconductor wafer 10, and then a mask layer 20C (e.g., a photoresist layer) is formed on the semiconductor wafer 10 by a third photolithography step with the same mask used in the above-mentioned step of FIG. 2A, and the mask layer 20C covers other regions except the third region 10C to expose the third region 10C. Then, a third ion implantation step is performed on the semiconductor wafer 10 to dope the third region 10C with ions with a concentration of Y.

Next, as shown in FIG. 2D, after the mask layer 20C is removed, a photoresist layer (not shown) is re-formed on the semiconductor wafer 10, and then a mask layer 20D (e.g., a photoresist layer) is formed on the semiconductor wafer 10 by a fourth photolithography step with the same mask used in the above-mentioned step of FIG. 2A. the mask layer 20D covers other regions except the fourth region 10D, exposing the fourth region 10D. Then, a fourth ion implantation step is performed on the semiconductor wafer 10, so as to dope the fourth region 10D with ions with a concentration of Z.

It is worth noting that when performing the lithography step (such as the steps in FIG. 2A-2D above), the same mask is used, and the focal length of the exposure light is adjusted to control the exposure region, for example, the exposure light is focused on a specific region, so that only this region can be successfully exposed, while other regions cannot be successfully exposed. In other words, it is only necessary to use the same mask to expose different regions in sequence. For example, in the step of FIG. 2A, the exposure light is focused on the upper left half of the semiconductor wafer 10, therefore, the region located in the upper left half (for example, the first region 10A) is exposed, and other regions are not exposed. After another photoresist layer is re-formed in FIG. 2B, the exposure light can be focused on the upper right half of the semiconductor wafer 10, therefore, the region located in the upper right half (for example, the second region 10B) is exposed, and other regions are not exposed. And so on in other regions. In this way, the effects of saving the mask and reducing the cost can be achieved.

Preferably, the ion implantation concentrations W, X, Y and Z are different from each other. And preferably, they have a certain proportional relationship (e.g., linear relationship), which makes it easier for the detector to calculate the electrical influence brought by the change of ion implantation concentration in the subsequent steps.

In the above steps, the photolithography step and ion implantation step are cycling performed. If the semiconductor wafer 10 is divided into more or less regions, the number of cycles of the lithography step and the ion implantation step can also be adjusted. In addition, in this embodiment, since the first ion implantation step to the fourth ion implantation step are performed on the first region 10A to the fourth region 10D respectively, the ion implantation concentrations of the first region 10A, the second region 10B, the third region 10C and the fourth region 10D are independent of each other and are not affected by each other.

Subsequently, electronic components (e.g., transistors and capacitors) can be formed in various regions of the semiconductor wafer 10 at the same time, and then WATs of these electronic components can be performed to obtain experimental results of the effects of different process parameters on the electronic components. For example, different ion implantation concentrations affect the performance of transistors.

With the above method, ion implantation can be performed on different regions on the same semiconductor wafer 10, and then the electrical characteristics of electronic components in each region can be measured respectively. Therefore, multiple experimental data can be measured without using multiple semiconductor wafers (for example, the electrical influence data of ion implantation concentration on electronic components can be measured). The purpose of saving semiconductor wafers and further saving cost can be achieved.

It is worth noting that, in the steps of the present invention, the lithography step and the ion implantation step are sequentially performed in different regions, and the electronic components in each region are formed after the ion implantation steps in each region are completed, and the electrical characteristics of each electronic component are measured in sequence. Therefore, preferably, in the steps of the present invention, the photolithography step and the ion implantation step are continuously performed between different regions, in other words, other steps are not performed during the cycle of the photolithography step and the ion implantation step, and other steps will not be performed until all regions are ion implanted. In this way, since each ion implantation is carried out in a similar environment, the accuracy of the experimental results can be improved.

In the above embodiments, ion implantation with different concentrations is performed in different regions of the same wafer, that is to say, the influence of ion implantation with different concentrations on the experimental results can be obtained through testing. In other embodiments of the present invention, different parameter tests can also be performed in different regions of the same wafer. For example, the same pattern can be exposed with different exposure energies in different regions of the same wafer, so that the most suitable critical dimension (CD) can be tested to improve the subsequent process efficiency.

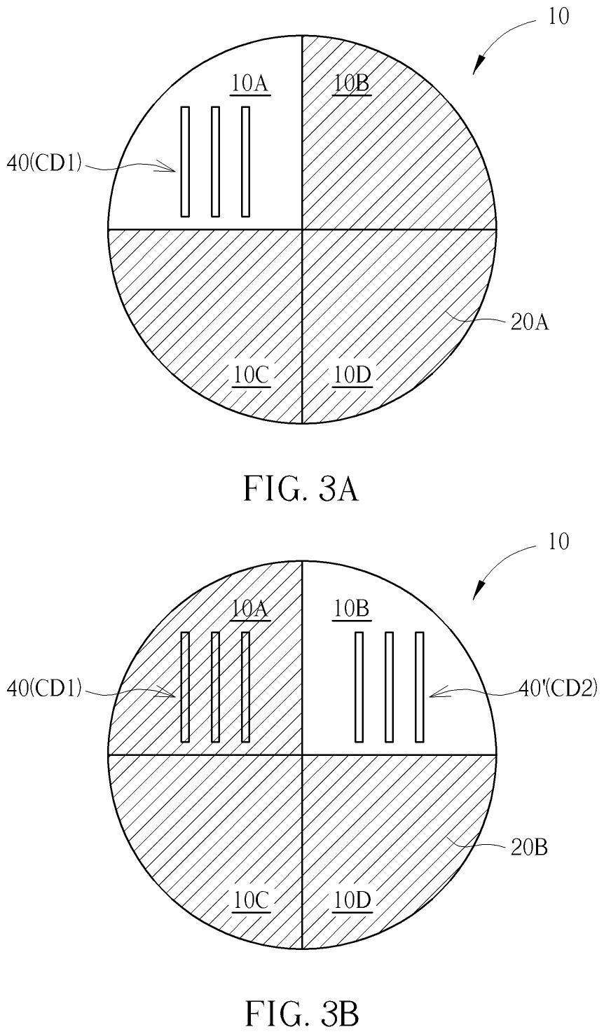

For example, FIG. 3A and FIG. 3B show top views of a semiconductor wafer for testing the influence of different exposure energies on critical dimensions of different regions according to another embodiment of the present invention. First, as shown in FIG. 3A, a photoresist layer (not shown) is formed, and then a first lithography step (including exposure and development steps) is used to remove part of the photoresist layer and to form a mask layer 20A on the semiconductor wafer 10, the mask layer 20A exposes the first region 10A and covers other regions, and a pattern 40 is formed in the first region 10A. The exposure energy of the first lithography step is adjusted (for example, the exposure energy is E1), and after the pattern is formed, the critical dimension of the pattern is recorded (for example, the critical dimension CD1).

Next, as shown in FIG. 3B, in the second region 10B, after removing the mask layer 20A, a photoresist layer (not shown) is formed again, and a second lithography step (exposure and development step) is used to remove part of the photoresist layer to form a mask layer 20B on the semiconductor wafer 10, the mask layer 20B exposes the second region 10B and covers other regions, and a pattern 40′ is formed in the second region 10B. The exposure energy of the second lithography step is adjusted (for example, the exposure energy is E2), and after the pattern 40′ is formed, the exposure critical dimension of the pattern is recorded (for example, the exposure critical dimension CD2).

Subsequently, patterns may be formed in the third region 10C and the fourth region 10D respectively, the exposure energy of the lithography step may be adjusted, and the exposure critical dimension of the patterns may be recorded. Since the steps are similar to those mentioned above, they will not be repeated here.

Similarly, in subsequent steps, electronic components (e.g., transistors and capacitors) can be formed in various regions of the semiconductor wafer 10 at the same time, and then WATs of these electronic components can be performed to obtain experimental results of the effects of different process parameters on the electronic components. For example, different exposure energies affect the performance of transistors. With the above method, the influence of different exposure energies on the critical dimension of the pattern can be measured on the same wafer, and then the better exposure energy can be found out to improve the yield of the subsequent semiconductor manufacturing process.

Similarly, in this embodiment, for example, in the steps shown in FIG. 3A and FIG. 3B, the same mask can be used to perform photolithography steps respectively, so as to achieve the effect of saving masks.

The invention is characterized in that, in the wafer testing step, in order to reduce the loss of the wafer, the wafer can be divided into different regions, and respective processes and electrical tests can be performed in different regions. Therefore, different regions can provide different test parameters and measurement results. In this way, multiple sets of experimental results can be measured on the same wafer, thus reducing wafer loss and cost.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for detecting optimal production conditions of wafers, comprising:
providing a wafer, wherein a plurality of regions are defined on the wafer, and the plurality of regions at least comprise a first region and a second region;
performing a first photolithography step to expose the first region of the plurality of regions;
performing a first ion implantation step to dope ions in the first region, wherein the first region has a first ion implantation concentration;
performing a second photolithography step to expose the second region of the plurality of regions;
performing a second ion implantation step to dope ions in the second region, wherein the second region has a second ion implantation concentration; and
detecting the electrical characteristics of the first region and the second region respectively.

2. The method according to claim 1, wherein the plurality of regions further comprise a third region and a fourth region, and the method further comprising:
performing a third photolithography step to expose the third region of the plurality of regions;
performing a third ion implantation step to dope ions in the third region, wherein the first region has a third ion implantation concentration;
performing a fourth photolithography step to expose the fourth region of the plurality of regions;
performing a fourth ion implantation step to dope ions in the fourth region, wherein the fourth region has a fourth ion implantation concentration;
detecting the electrical characteristics of the first region, the second region, the third region and the fourth region respectively.

3. The method according to claim 2, wherein the first ion implantation concentration, the second ion implantation concentration, the third ion implantation concentration and the fourth ion implantation concentration are different from each other.

4. The method according to claim 1, wherein the method to expose the first region and the second region comprising:
forming a first photoresist layer comprehensively on the wafer;
using a first mask to remove part of the first photoresist layer by the first photolithography step and to expose the first region;
removing the first photoresist layer completely and re-form a second photoresist layer on the wafer;
using the first mask to remove part of the second photoresist layer by the second photolithography step and to expose the second region.

5. The method according to claim 4, wherein when the second region is exposed, the first region is covered by the second photoresist layer.

6. The method according to claim 1, wherein the method to expose the first region and the second region comprising:
forming a first photoresist layer comprehensively on the wafer;
performing the first photolithography step to focus an exposure light in the first region, and to remove the first photoresist layer in the first region;
removing the first photoresist layer and forming a second photoresist layer on the wafer;
performing the second photolithography step to focus another exposure light in the second region, and to remove the second photoresist layer in the second region.

7. The method according to claim 1, wherein the step of detecting the electrical characteristics of the first region and the second region respectively comprising:
forming at least one electronic component in the first region and the second region respectively; and
performing a wafer acceptance test (WAT) on the electronic components in the first region and the second region respectively.

8. A method for detecting optimal production conditions of wafers, comprising:
providing a wafer, wherein a plurality of regions are defined on the wafer, and the plurality of regions at least comprise a first region and a second region;
performing a first photolithography step to exposing the first region of the plurality of regions with a first exposure energy, and to form a first pattern in the first region, wherein the first pattern has a first exposure critical dimension;
performing a second photolithography step to expose the second region of the plurality of regions with a second exposure energy, and to form a second pattern in the second region, wherein the second pattern has a second exposure critical dimension; and
detecting the electrical characteristics of the first region and the second region respectively.

9. The method according to claim 8, wherein a same mask is used when performing the first lithography step and the second lithography step.

10. The method according to claim 8, wherein the step of detecting the electrical characteristics of the first region and the second region respectively comprising:
forming at least one electronic component in the first region and the second region respectively; and
performing a wafer acceptance test (WAT) on the electronic components in the first region and the second region respectively.
